(19) United States
(12) Patent Application Publication
(10) Pub. No.: US 2012/0018780 A1
(43) Pub. Date: Jan. 26, 2012

(54) SEMICONDUCTOR DEVICE AND METHOD FOR MANUFACTURING SAME

(76) Inventors: Kazuaki Iwasawa, Kanagawa-ken (JP); Shigeo Kondo, Saitama-ken (JP); Hiroshi Akahori, Kanagawa-ken (JP); Kiyohito Nishihara, Kanagawa-ken (JP); Yingkang Zhang, Kanagawa-ken (JP); Masaki Kondo, Kanagawa-ken (JP); Hidenobu Nagashima, Mie-ken (JP); Takashi Ichikawa, Saitama-ken (JP)

(21) Appl. No.: 13/075,665

(22) Filed: Mar. 30, 2011

(30) Foreign Application Priority Data
Jul. 20, 2010 (JP) 2010-163381

(51) Int. Cl. H01L 29/772; H01L 21/28

(52) U.S. Cl. 257/192; 438/585; 257/E21.158; 257/E29.242

(57) ABSTRACT

According to one embodiment, a method is disclosed for manufacturing a semiconductor device. A side face parallel to a channel direction of a plurality of gate electrodes provided via a gate insulating film above a semiconductor substrate is included as a part of an inner wall of an isolation groove provided between the adjacent gate electrodes. The method can include forming a protection film covering the side face of the gate electrode. The method can include etching the semiconductor substrate using the gate electrode as a mask to form the isolation groove. The side face of the gate electrode is covered with the protection film. The method can include forming a first insulating film by oxidizing a surface of the isolation groove to fill a bottom portion of the isolation groove. In addition, the method can include forming a second insulating film on the first insulating film to fill an upper portion of the isolation groove including the side face of the gate electrode.

### CROSS-REFERENCE TO RELATED APPLICATIONS

This application is based upon and claims the benefit of priority from the prior Japanese Patent Application No. 2010-163381, filed on Jul. 20, 2010; the entire contents of which are incorporated herein by reference.

### FIELD

Embodiments described herein relate generally to a semiconductor device and a method for manufacturing the same.

### BACKGROUND

In order to enhance the performance and achieve a reduction in the cost of a highly-integrated LSI, there is a need for a new progress in the microfabrication technique in the LSI manufacturing process. For example, a reduction in the size of an element isolation region is directly linked to a reduction in the element area, contributing to a reduction in the cost. On the other hand, the isolation characteristics of the element isolation region govern the operation speed and power consumption of the LSI. Then, the insulation properties of the element isolation region should be maintained also in highly-miniaturized structures.

STI (Shallow Trench Isolation) widely employed as the element isolation technique for LSIs has an element isolation structure in which a fine isolation groove is filled with an insulating film. As the integration level of LSIs increases, this isolation groove is now reaching a very fine trench width equal to or less than 20 nm, for example.

On the other hand, in order to maintain the insulation properties of the element isolation structure, the depth of the isolation groove needs to be kept constant. As a result, with progress in high integration, the aspect ratio of the isolation groove of STI increases, thus possibly posing a problem that the filling with an insulating film becomes difficult. Therefore, there is a need for a new technique for forming an insulating film inside a finely-processed isolation groove having a large aspect ratio.

### BRIEF DESCRIPTION OF THE DRAWINGS

FIG. 1 is a schematic view illustrating a plane configuration of a semiconductor device according to a first embodiment;

FIG. 2A to FIG. 4B are partial cross-sectional views schematically illustrating manufacturing processes of the semiconductor device according to the first embodiment;

FIG. 5 is a schematic view illustrating a partial cross-section of the semiconductor device according to the first embodiment;

FIGS. 6A to 6C are schematic views illustrating a part of the cross-section of a semiconductor wafer according to a comparative example;

FIGS. 7A and 7B are schematic cross-sectional views illustrating structural parameters of the semiconductor device according to the first embodiment;

FIG. 8A to FIG. 9B are partial cross-sectional views schematically illustrating manufacturing processes of a semiconductor device according to a second embodiment; and

FIG. 10A to FIG. 11B are partial cross-sectional views schematically illustrating manufacturing processes of a semiconductor device according to a third embodiment.

### DETAILED DESCRIPTION

In general, according to one embodiment, a method is disclosed for manufacturing a semiconductor device. A side face parallel to a channel direction of a plurality of gate electrodes provided via a gate insulating film above a semiconductor substrate is included as a part of an inner wall of an isolation groove provided between the adjacent gate electrodes. The method can include forming a protection film covering the side face of the gate electrode. The method can include etching the semiconductor substrate using the gate electrode as a mask to form the isolation groove. The side face of the gate electrode is covered with the protection film. The method can include forming a first insulating film by oxidizing a surface of the isolation groove to fill a bottom portion of the isolation groove. In addition, the method can include forming a second insulating film on the first insulating film to fill an upper portion of the isolation groove including the side face of the gate electrode.

Hereinafter, embodiments of the invention will be described with reference to the drawings. In the following embodiments, similar components in the drawings are marked with like reference numerals, and a detailed description is omitted as appropriate. Different components will be suitably described.

### First Embodiment

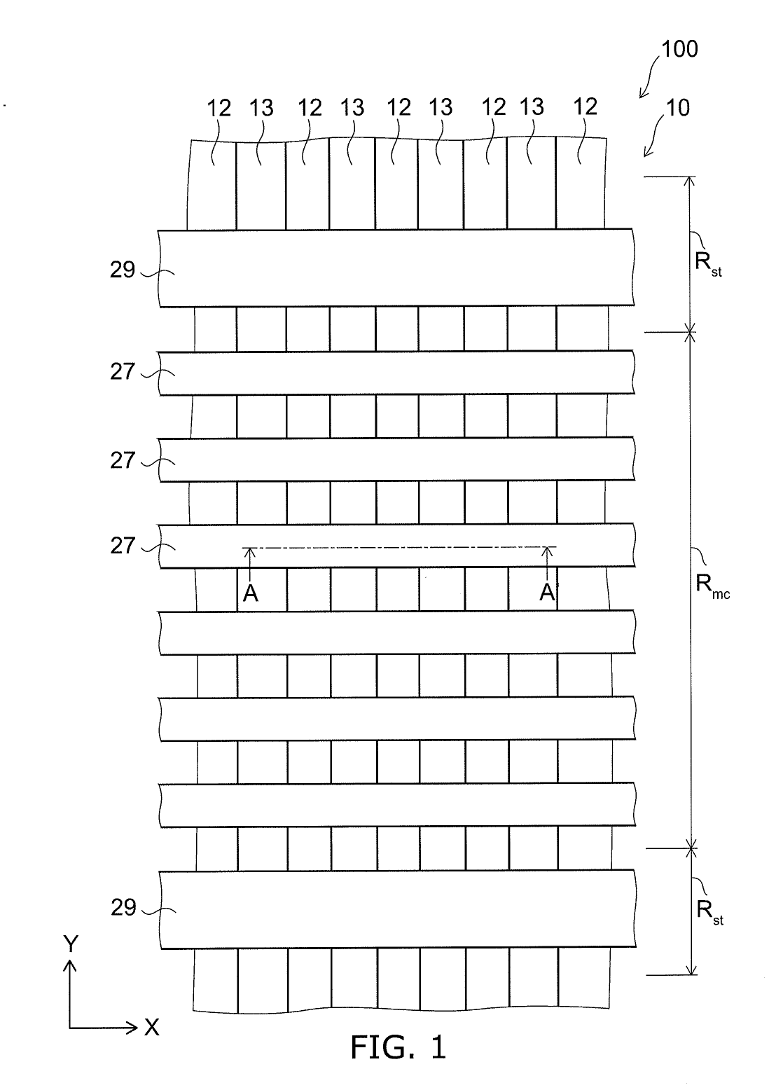

FIG. 1 is a planar configuration view schematically illustrating a semiconductor device 100 according to a first embodiment. The semiconductor device 100 is a NAND-type flash memory, for example, and FIG. 1 illustrates the configuration of a memory array section. The NAND-type flash memory includes a memory array section 10 for storing data and a peripheral circuit section (not illustrated) driving the memory array section 10.

As illustrated in FIG. 1, a memory cell region R_{mc} and a selection transistor region Rₛₜ are arranged in the memory array section 10, wherein the memory cell region R_{mc} is provided between two selection transistor regions Rₛₜ. In the Y direction in this view, a plurality of memory strings 13 and a plurality of STI's 12 are alternately arranged penetrating through both the memory cell region R_{mc} and the selection transistor region Rₛₜ. The STI 12 isolates the adjacent memory strings 13 from each other.

Furthermore, a plurality of control gate electrodes 27 and selection gate electrodes 29 are provided crossing the memory strings 13 and STI's 12 in the X direction. A memory cell is formed at a place where the memory string 13 intersects with the control gate electrode 27, and a selection transistor is formed at a place where the memory string 13 intersects with the selection gate electrode 29.

Corresponding to the progress in the increasing capacity of the NAND-type flash memory, the structure of the memory array section 10 is miniaturized, and for example, the horizontal width of STI 12 is now approaching to 20 nm or less.

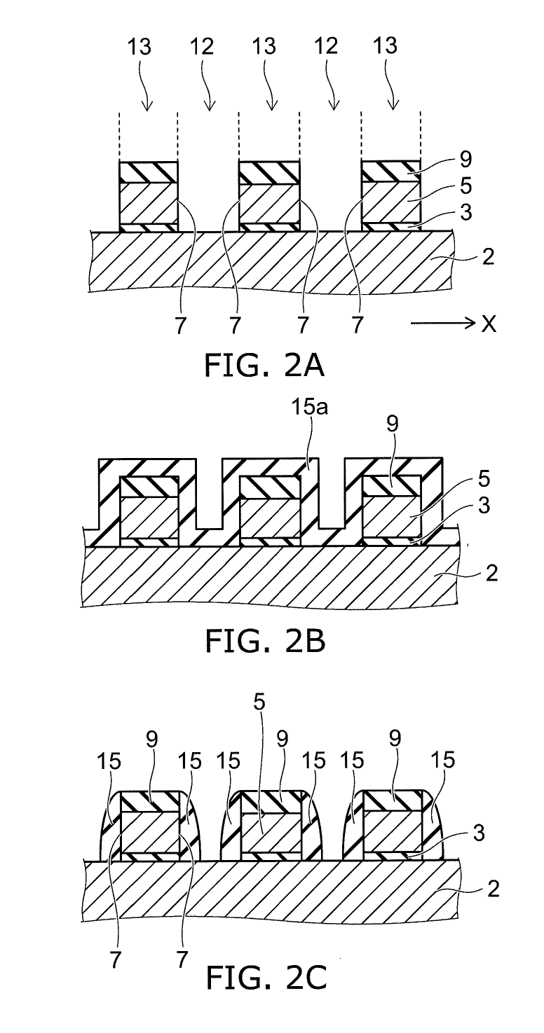

In the embodiment, a method for manufacturing the semiconductor device 100 will be described while illustrating a part of the memory cell regions R_{mc} provided in the memory array section 10. Hereinafter, FIG. 2A to FIG. 4B schematically illustrate an A-A cross section of the memory cell region R_{mc} (see FIG. 1).

As illustrated in FIG. 2A, the semiconductor device 100 includes a plurality of gate electrodes 5 provided via a gate insulating film 3 above the semiconductor substrate 2, wherein a side face 7 parallel to a channel direction of the gate electrode 5 serves as a part of an inner wall of an isolation groove provided between the adjacent gate electrodes 5.

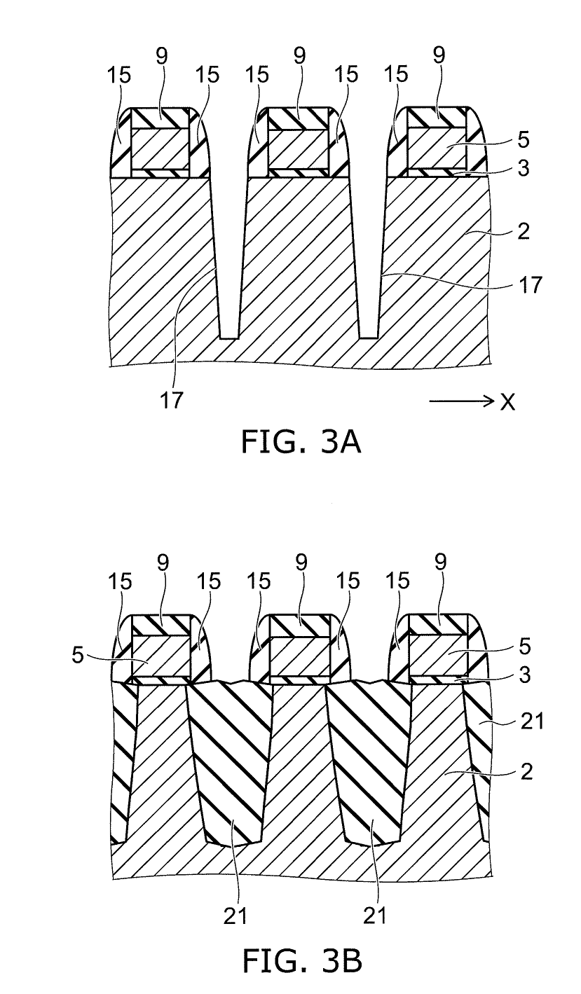

Here, the channel direction is the Y direction in which the memory strings 13 formed in a stripe shape extend. The X direction orthogonal to the Y direction is the channel width direction. The isolation groove means a groove comprising a trench 17 formed in the semiconductor substrate 2 and a space between the adjacent gate electrodes 5 above the trench 17. The trench 17 is a bottom portion of the isolation groove, while the space between the gate electrodes 5 is the upper part of the isolation groove (see FIG. 3A). For example, the STI 12 of FIG. 1 is formed by filling the isolation groove with an insulating film.

In the embodiment, an SiON film with a thickness of 8 nm to serve as the gate insulating film 3 and a polysilicon film with a thickness of 90 nm to serve as the gate electrode 5 are stacked on the semiconductor substrate 2. Furthermore, a silicon nitride film (SiN film) 9 with a thickness of 70 nm to serve as an etching mask of reactive ion etching (RIE) is stacked.

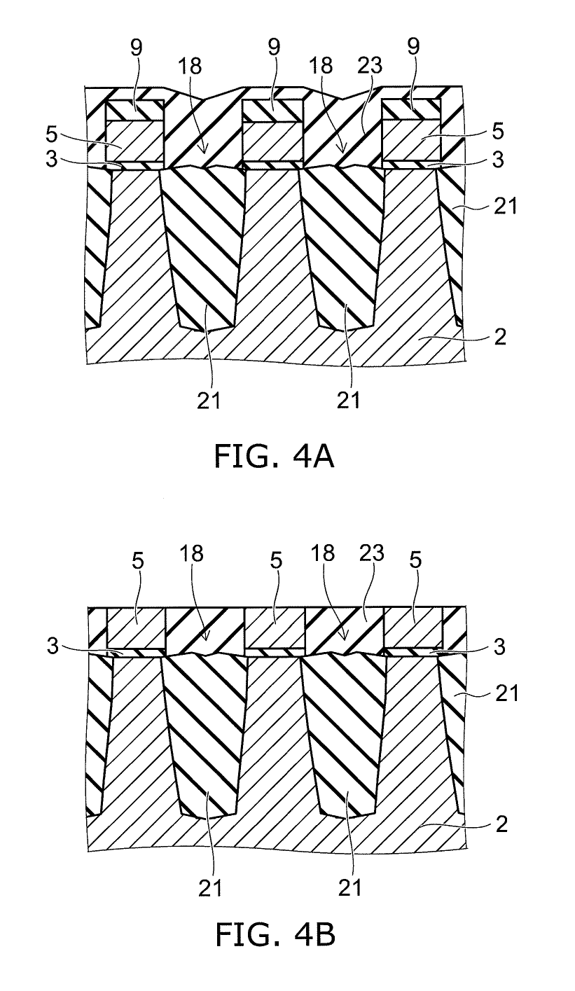

The SiN film 9 can be also used as a stopper of chemical mechanical polishing (CMP) (see FIG. 4B). For the semiconductor substrate 2, a silicon substrate (wafer) can be used, for example.

For example, with a stripe-shaped silicone oxide film (SiO₂ film) formed on the SiN film 9 as a mask, the SiN film 9, polysilicon film, and SiON film can be sequentially etched. In etching, RIE can be used.

Then, as illustrated in FIG. 2A, the gate electrode 5 is formed via the gate insulating film 3 above the semiconductor substrate 2. The gate electrodes 5 are formed in a stripe shape in the Y direction in which the memory string 13 extends, and are arranged parallel to each other in the X direction with a space therebetween in which the STI 12 is subsequently formed.

Next, a protection film covering the side face 7 of the gate electrode 5 is formed.

As illustrated in FIG. 2B, on the surface of the semiconductor substrate 2 on which the gate electrode 5 is formed, an SiN film 15a serving as a protection film 15 is formed using ALD (Atomic Layer Deposition), for example.

Subsequently, as illustrated in FIG. 2C, the SiN film 15a is etched, with the protection film 15 left on the side face of the gate electrode 5. For example, the anisotropy of RIE can be utilized which makes the etching rate in the direction perpendicular to the surface of the semiconductor substrate 2 faster than the etching rate in the direction parallel to the surface of the semiconductor substrate 2. As the etching gas, carbon tetrafluoride (CF₄) can be used, for example.

This makes it possible to remove the SiN film 15a formed on the gate electrode 5 and the SiN film 15a formed on the surface of the semiconductor substrate 2 between the adjacent gate electrodes 5 and thereby expose the surface of the semiconductor substrate 2 in between the gate electrodes 5, while leaving the protection film 15 on the side face 7 of the gate electrode 5.

Next, as illustrated in FIG. 3A, with the gate electrode 5, whose side face 7 is covered with the protection film 15, as a mask, the trench 17 which is the bottom portion of the isolation groove is formed. For example, etching is performed in the direction perpendicular to the surface of the semiconductor substrate 2 using an RIE condition with anisotropy. As the etching gas, a mixed gas of hydrogen bromide (HBr), oxygen (O₂), and CF₄ can be used, for example.

This makes it possible to suppress the etching in the horizontal direction parallel to the surface of the semiconductor substrate 2 and form the trench 17 in the depth direction from the surface of the semiconductor substrate 2 exposed between the adjacent gate electrodes 5. The frontage of the trench 17 can be formed with the same width as that in the X direction of the semiconductor substrate 2 exposed between the gate electrodes 5.

Moreover, the trench 17 is formed uniformly in the left and right directions on both sides of the gate electrode 5. A positional deviation between the upper and bottom portions of the isolation groove produced in the interface between the protection film 15 and the semiconductor substrate 2 also can be formed uniformly in the left and right directions.

Next, the surface of the semiconductor substrate 2 exposed to the inner wall of the isolation trench 17 is thermally oxidized to form the SiO₂ film 21 which is a first insulating film.

Because the volume of the SiO₂ film 21 formed by thermal oxidation is larger than that of the oxidized region of the semiconductor substrate 2, the inside of the trench 17 can be filled with the SiO₂ film 21, as illustrated in FIG. 3B.

As described above, the trench 17 is formed uniformly in the left and right directions on both sides of the gate electrode 5, and the thermal oxidation of the semiconductor substrate 2 exposed to the inside of the trench 17 proceeds uniformly in the left and right directions. Therefore, the SiO₂ film 21 filling the trench 17 is also formed uniformly, and the distances from the center of the SiO₂ film 21 to the gate insulating film 3 and gate electrode 5 are equal.

In FIG. 3A, for example, if the spacing in the X direction between the adjacent gate electrodes 5 is set to 20 nm and the width in the X direction of the protection film 15 to 5 nm, then the width of the frontage of the trench 17 becomes 10 nm. Furthermore, if the depth of the trench 17 is set to 220 nm, the aspect ratio of the trench 17 becomes 22.

It is thus difficult to fill the inside of the trench 17 having such a narrow frontage and large aspect ratio with the SiO₂ which is formed using high density plasma-chemical vapor deposition (HDP-CVD) or CVD using TEOS (TetraEthOxySilane) and O₃ gas (hereinafter referred to as TEOS/O₃), for example.

In contrast, as in the embodiment, if the inner surface of the trench 17 is thermally oxidized to form the SiO₂ film 21, the inside of the trench 17 also can be filled due to the volume expansion of the SiO₂ film 21. Then, a high quality SiO₂ film with suppressed void or seam can be formed inside the trench 17.

On the other hand, since the protection film 15 is formed on the side face 7 of the gate electrode 5, the silicon contained in the gate electrode 5 is not oxidized but the thermal oxide film is formed only in the inside of the trench 17. Furthermore, as the protection film 15, for example, an oxidation-resistant SiN film is used, so that the degradation of the gate electrode 5 and gate insulating film 3 due to the oxidization can be also prevented.

Next, as illustrated in FIG. 4A, an SiO₂ film 23 which is a second insulating film is formed on the SiO₂ film 21, so that an upper portion 18 of the isolation groove sandwiched by the side faces 7 of the gate electrode 5 can be filled with the SiO₂ film 23.

For example, the protection film 15 is etched using rare fluoric acid, phosphoric acid heated to approximately 150° C., or the like, and subsequently the SiO₂ film 23 is formed by a method, such as HDP-CVD, TEOS/O₃, a coating method, LP-CVD, or ALD.

The trench 17 which is the bottom portion of the isolation groove is filled with the SiO₂ film 21, while an upper portion 18 of the isolation groove sandwiched by the side faces 7 of the gate electrode 5 is a relatively shallow groove having a narrow frontage but a small aspect ratio. Therefore, the trench 17 can be easily filled using the above-described HDP-CVD, TEOS/O₃, or the like.

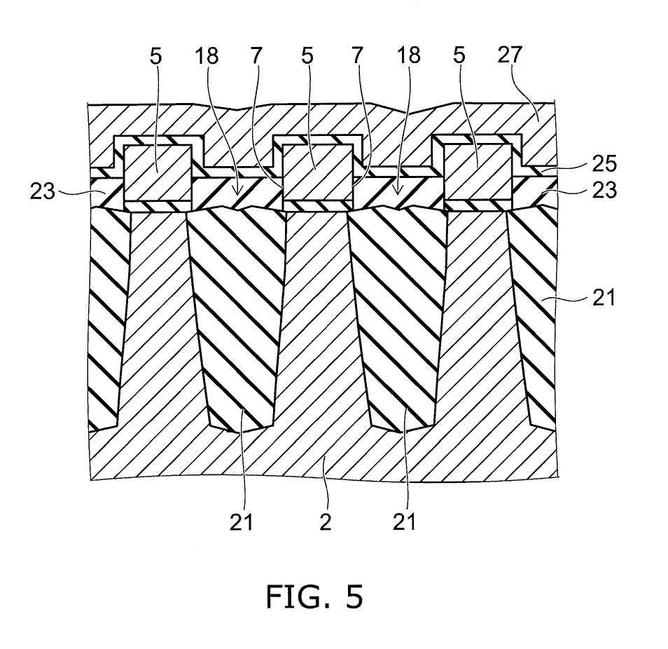

In the above-described embodiment, an example of etching and removing the protection film 15 has been shown, however, the protection film 15 can be left. Then, on the side face of the gate electrode 5, the protection film 15 may be used also as a part of an interpoly insulating film 25 (see FIG. 5) isolating the control gate electrode 27 (see FIG. 5) from the gate electrode 5.

Next, as illustrated in FIG. 4B, the surface of the SiO₂ film 23 is planarized using CMP. In this case, the SiN film 9 formed on the gate electrode 5 can serve as a stopper to prevent polishing of the gate electrode 5.

Next, as illustrated in FIG. 5, the surface of the SiO₂ film 23 filling the upper portion 18 of the isolation groove is etched back, and the control gate electrode 27 is formed via the interpoly insulating film 25.

The semiconductor device 100 produced in this manner comprises the gate electrode 5 which is formed via the gate insulating film 3 above the semiconductor substrate 2, and the isolation groove including, as a part of the inner wall, the side face 7 parallel to the channel direction of the gate electrode 5.

The bottom portion (trench 17) of the isolation groove is filled with the SiO₂ film 21 which is the first insulating film, while the upper portion 18 of the isolation groove is filled with the SiO₂ film 23 which is the second insulating film formed on the SiO₂ film 21. For example, the density of the SiO₂ film 23 formed using HDP-CVD or TEOS/O₃ becomes lower than the density of the SiO₂ film 21 which is a thermally-oxidized film.

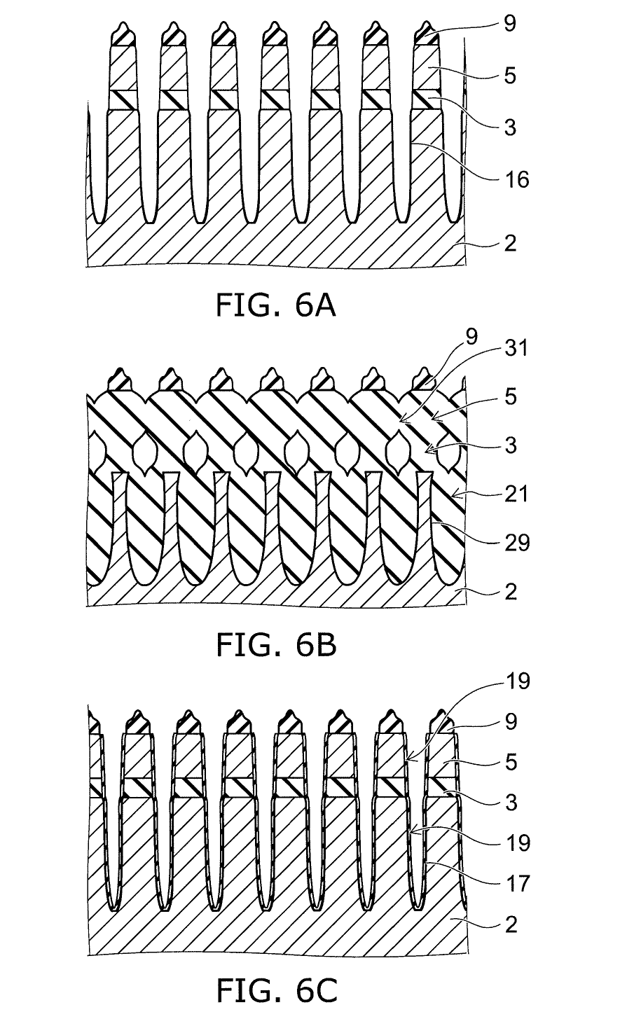

FIGS. 6A to 6C are schematic views illustrating a part of the cross-section of the semiconductor substrate 2 according to a comparative example.

FIG. 6A illustrates a state where the gate electrode 5 is formed via the gate insulating film 3 above the semiconductor substrate 2. The SiN film 9 is formed on the gate electrode 5. An isolation groove 16 is formed between the adjacent gate electrodes 5. The isolation groove 16 is continuously etched from the surface of the SiN film 9 to a predetermined depth of the semiconductor substrate 2.

FIG. 6B illustrates the cross-section after thermally oxidizing the surface of the semiconductor substrate 2 illustrated in FIG. 6A. The groove of the semiconductor substrate 2 which is the bottom portion of the isolation groove 16 is filled with the SiO₂ film 21. Furthermore, also in the upper portion of the isolation groove 16, the gate electrode 5 is oxidized and the upper portion of the groove is plugged with an SiO₂ film 31.

In a region 29 sandwiched by the bottom portion of the isolation groove 16, a part of the semiconductor substrate 2 remains. In contrast, it is apparent that the whole of the gate electrode 5 is oxidized and turned into SiO₂.

On the other hand, FIG. 6C illustrates the cross-section in a state where the protection film 19 is formed on the surface of the semiconductor substrate 2 illustrated in FIG. 6A and is subsequently thermally oxidized. The protection film is an SiN film with a thickness of approximately 5 nm formed by ALD.

As illustrated in FIG. 6C, neither the semiconductor substrate 2 nor the gate electrode 5 is thermally oxidized, which indicates that the oxidization is suppressed by the protection film 19.

It is understood that if the protection film 19 is not formed, the oxidization proceeds from the side face of the gate electrode 5 and the upper portion of the isolation groove 16 is plugged with the SiO₂ film, as illustrated in FIG. 6B. Furthermore, the whole of the gate electrode 5 may turn into SiO₂ and may not serve as a floating gate, for example.

On the other hand, in the bottom portion of the isolation groove 16, the thermal oxidation proceeds and the isolation groove 16 is filled with the SiO₂ film. Then, under the gate electrode 5, a part 29 of the semiconductor substrate 2 serving as the channel remains.

That is, with the protection film 19 being left on the side face of the gate electrode 5, the thermal oxidation is performed with the bottom portion of the isolation groove 16 exposed, so that the part 29 serving as the channel can be left under the gate electrode 5 and only the bottom portion of the isolation groove 16 can be filled with the SiO₂.

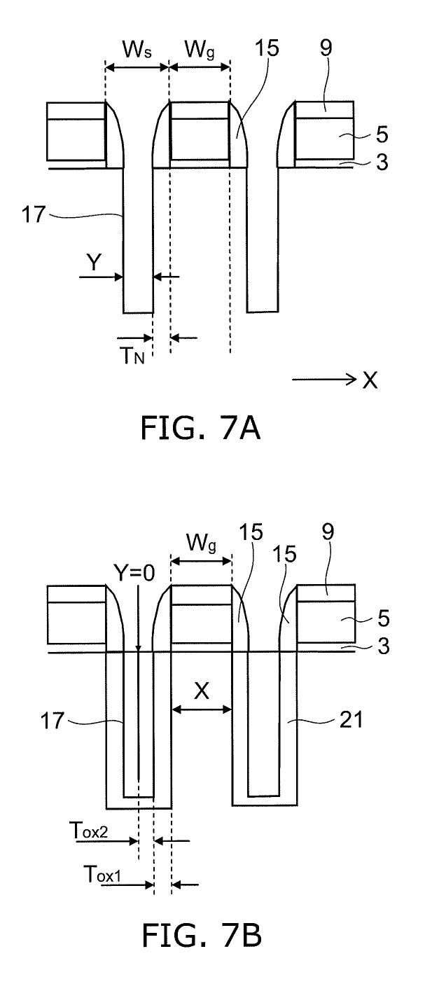

FIGS. 7A and 7B are schematic cross-sectional views illustrating structural parameters of the semiconductor device 100 according to the embodiment. FIG. 7A illustrates a cross-section in a state where the trench 17 is formed in the semiconductor substrate 2, and FIG. 7B illustrates a cross-section after thermally oxidizing the inner surface of the trench 17.

As illustrated in FIG. 7A, the width in the X direction of the trench 17 is denoted by Y, the width of the gate electrode 5 is denoted by W_{g}, and the spacing between the adjacent gate electrodes 5 is denoted by W_{S}. The width of the protection film 15 formed on the side face of the gate electrode 5 is denoted by T_{N}.

On the other hand, as illustrated in FIG. 7B, the width of the semiconductor substrate 2 thermally oxidized in the inner surface of the trench 17 is denoted by T_{OX1}, and the width of the SiO₂ film 21 expanding into the trench 17 is denoted by T_{OX2}. Moreover, the channel width under the gate electrode 5 is denoted by X.

When the inside of the trench 17 is filled with the SiO₂ film 21, the width Y in the X direction of the trench 17 is expressed by the following equation.

Y=2T_{OX2}

On the other hand, the ratio of the width T_{OX1} of the thermally oxidized semiconductor and the width T_{OX2} of the SiO₂ film 21 expanding into the trench 17 is expressed by the following equation.

T_{OX1}:T_{OX2}=0.44:0.56

T_{OX1} in terms of Y is expressed by the following equation.

T_{OX1}=0.39Y

When the inside of the trench 17 is filled with the SiO₂ film 21, the supply of oxygen to the inside of the trench 17 stops and thermal oxidation of the semiconductor substrate 2 stops. That is, the thermal oxidation of the inner surface of the trench 17 proceeds by a width corresponding to 39% of the opening width Y of the trench 17 and then stops.

Furthermore, the channel width X under the gate electrode 5 is expressed by the following equation.

X=W_{g}−2×(T_{OX1}−T_{N})

Moreover, the opening width Y of the trench 17 is expressed by the following equation.

Y=W_{S}−2T_{N}

Therefore, the channel width X is expressed by the following equation.

X=W_{g}−2×(0.38W_{S}−1.78T_{N})

That is, the channel width X is determined by the width W_{g} of the gate electrode 5, the spacing W_{S} between the adjacent gate electrode 5, and the width T_{N} of the protection film 15.

On the other hand, when the width T_{N} of the protection film 15 satisfies the following equations, the thermal oxidation of the inner surface of the trench 17 proceeds to the lower portion of the gate electrode 5.

T_{N}<0.39Y

T_{N}<0.22W_{S}

That is, if the width T_{N} in the X direction of the protection film 15 is equal to or less than 22% of the spacing W_{S} between the gate electrodes 5, the oxidization of the inner surface of the trench 17 proceeds to the lower portion of the gate electrode 5. Then, the channel width X becomes smaller than the gate width W_{g}.

For example, in the NAND-type flash memory, the channel width X can be made smaller than the width W_{g} of the floating gate (gate electrode 5), and the coupling ratio can be increased. Then, the injection efficiency of carriers into the floating gate can be improved.

In the embodiment, on the semiconductor substrate 2, the gate insulating film 3 and gate electrode 5 are formed in advance and then the trench 17 is formed. Furthermore, the inside of the trench 17 is thermally oxidized so as to be filled utilizing the volume expansion of the SiO₂ film. This makes it possible to form an insulating film inside the isolation groove having a small width and a large aspect ratio and realize an STI structure having high insulating properties.

Furthermore, the channel width X formed under the gate electrode 5 can be controlled by the width T_{N} of the protection film 15 formed on the side face 7 of the gate electrode 5.

For example, as the capacity of the NAND-type flash memory continues to increase, not only the width of the STI 12 but also the width of the memory string 13 will narrow. Therefore, improving the accuracy of the channel width X also becomes important. Then, the channel width X can be controlled by the width W_{g} of the gate electrode 5, the spacing W_{S} between the gate electrodes 5, and the width T_{N} of the protection film 15. These structural parameters can be applicable with a relatively high accuracy, and thus with the method of manufacturing a semiconductor device according to the embodiment, the accurate control of the channel width X can be achieved.

### Second Embodiment

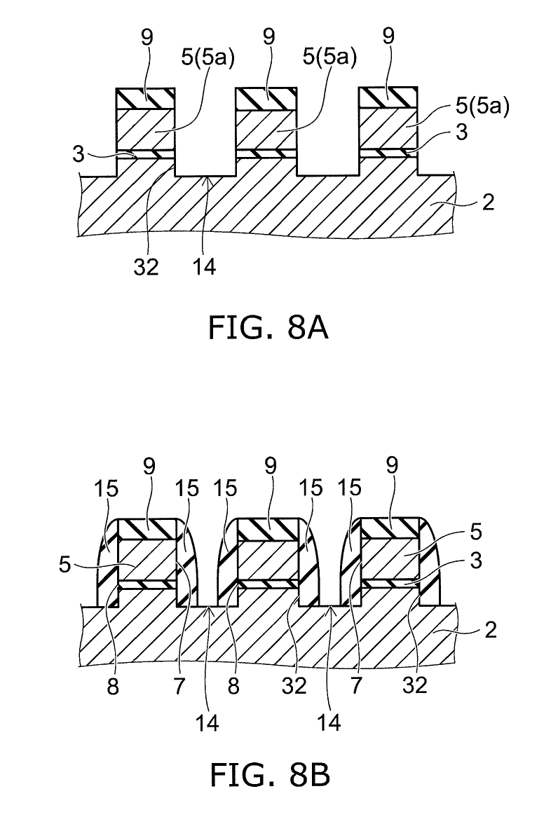

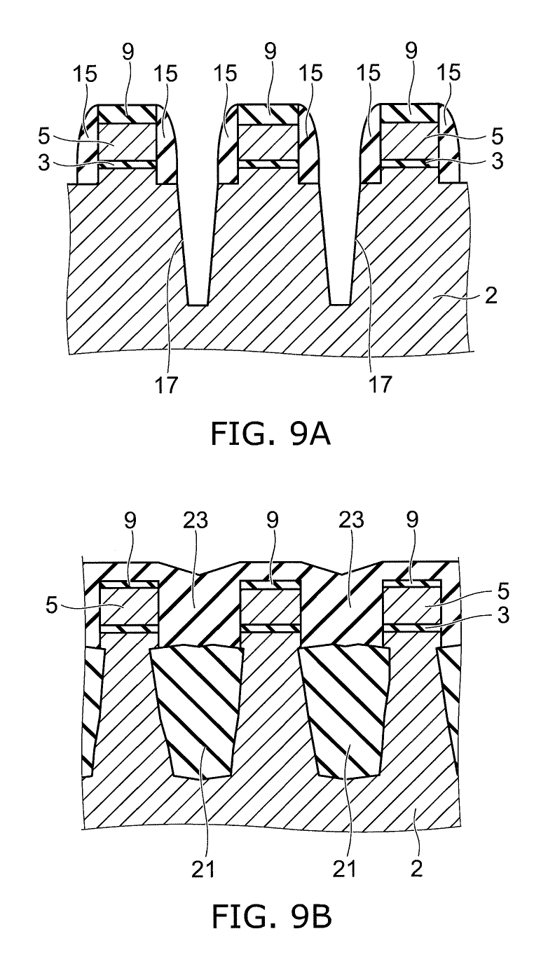

FIG. 8A to FIG. 9B are partial cross-sectional views schematically illustrating manufacturing processes of the semiconductor device 100 according to a second embodiment. These views illustrate the A-A cross section in the planar configuration illustrated in FIG. 1.

As illustrated in FIG. 8A, in the manufacturing method according to the embodiment, the gate electrode 5 is provided by etching the gate insulating film 3 formed on the semiconductor substrate 2, a conductive film 5a serving as the gate electrode 5 formed on the gate insulating film 3, and the semiconductor substrate 2.

The SiN film 9 is formed on the conductive film 5a, and a groove extending from the surface of the SiN film 9 to the semiconductor substrate 2 can be selectively formed using RIE, for example. The depth of a recess 14 formed in the semiconductor substrate 2 can be set to 10 nm, for example.

Next, as illustrated in FIG. 8B, the protection film 15 is formed on the side face 7 of the gate electrode 5, on the side face 8 of the gate insulating film 3, and on a side face 32 of the recess 14 formed in the semiconductor substrate 2. As described above, for the protection film 15, an SiN film formed by ALD can be used, for example.

Subsequently, as illustrated in FIG. 9A, with the gate electrode 5 having the protection film 15 formed on the side face 7 thereof as the mask, the semiconductor substrate 2 is etched to form the trench 17.

Specifically, as illustrated in FIG. 8B, between the adjacent protection films 15, the surface of the semiconductor substrate 2 exposed to the bottom surface of the recess 14 is etched using RIE, for example. As the etching gas, a mixed gas of HBr, O₂, and CF₄ can be used, for example. Then, utilizing the anisotropy of the etching, the trench 17 which is straightly etched in the depth direction from the surface of the semiconductor substrate 2 exposed to the bottom surface of the recess 14 can be formed.

Next, as illustrated in FIG. 9B, the inner surface of the trench 17 is thermally oxidized to form the SiO₂ film 21 and fill the inside of the trench 17 therewith.

Furthermore, above the SiO₂ film 21, the SiO₂ film 23 can be formed using, for example, HPD-CVD or TEOS/O₃ to fill the space between the adjacent gate electrodes 5.

In the method for manufacturing a semiconductor device according to the above-described embodiment, as illustrated in FIG. 8B and FIG. 9A, the cross section including the interface between the gate insulating film 3 and the semiconductor substrate 2 is completely covered by the protection film 15. This makes it possible to suppress the occurrence of a defect called “bird's beak” or the like, wherein the oxidization abnormally proceeds along the interface between the gate insulating film 3 and the semiconductor substrate 2 in thermally oxidizing the inner surface of the trench 17.

### Third Embodiment

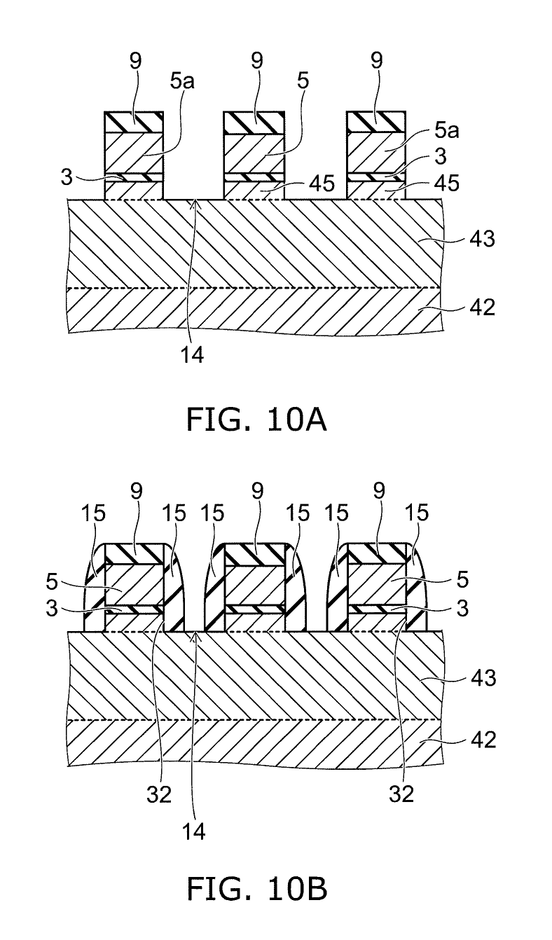

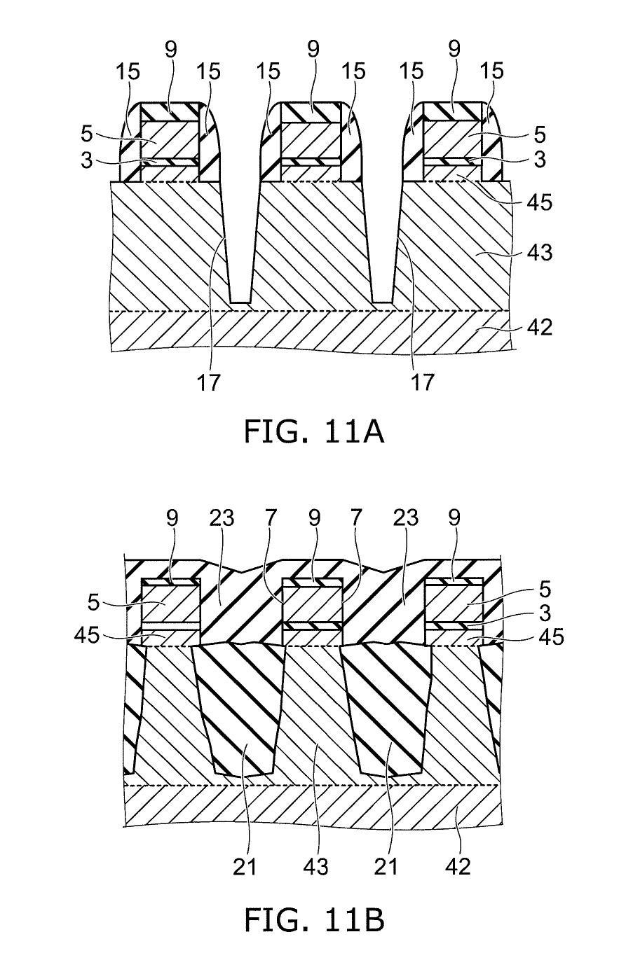

FIG. 10A to FIG. 11B are partial cross-sectional views schematically illustrating manufacturing processes of the semiconductor device 100 according to a third embodiment. These views illustrate the A-A cross section in the planar configuration illustrated in FIG. 1.

In the manufacturing method according to the embodiment, a wafer having a semiconductor layer 43 and a semiconductor layer 45 stacked on a semiconductor substrate 42 is used. For the semiconductor layer 43, a material, thermal oxidation of which progresses more quickly than the semiconductor layer 45, is used. For example, the semiconductor layer 43 can be a SiGe layer and the semiconductor layer 45 can be a silicon layer. For the semiconductor substrate 42, a silicon substrate can be used.

As illustrated in FIG. 10A, the gate insulating film 3 formed on the semiconductor layer 45, the conductive film 5a serving as the gate electrode 5, and the SiN film 9 are selectively etched, and further the semiconductor layer 45 is etched. This forms a groove extending from the surface of the SiN film 9 to the semiconductor layer 43. In the bottom portion of the groove, the recess 14 which is the etched semiconductor layer 45 is formed, so that the surface of the semiconductor layer 43 can be caused to be exposed to the bottom surface of the recess 14.

Next, as illustrated in FIG. 10B, the protection film 15 covering the side face 7 of the gate electrode 5, the side face 8 of the gate insulating film 3, and the side face 32 of the semiconductor layer 45 is formed.

Subsequently, as illustrated in FIG. 11A, with the gate electrode 5 having the protection film 15 formed in the side face 7 thereof as the mask, the semiconductor layer 43 is etched to form the trench 17.

Specifically, as illustrated in FIG. 10B, the surface of the semiconductor layer 43 exposed to the bottom surface of the recess 14 is etched using RIE, for example. Then, utilizing the anisotropy of the etching, the trench 17 which is straightly etched in the depth direction from the surface of the semiconductor layer 43 is formed.

Subsequently, as illustrated in FIG. 11B, the semiconductor layer 43 exposed to the inner surface of the trench 17 can be thermally oxidized to form the SiO₂ film 21 and fill the inside of the trench 17 therewith.

Furthermore, above the SiO₂ film 21, the SiO₂ film 23 can be formed using, for example, HDP-CVD or TEOS/O₃ to fill the space between the adjacent gate electrodes 5.

In the method for manufacturing the semiconductor device according to the embodiment, the trench 17 is formed in the semiconductor layer 43. The progress of thermal oxidation of the semiconductor layer 43 is quicker than the semiconductor layer 45 in which the channel is formed directly under the gate electrode 5. Therefore, for example, the thermal oxidation can be performed in a shorter time than a case where only the semiconductor layer 45 is provided above the semiconductor substrate 42, thereby filling the inside of the trench 17 with the SiO₂ film 21.

For this reason, even when the protection film 15 formed on the side face 7 of the gate electrode 5 is thin or when the oxidation resistance of the protection film 15 is poor, the thermal oxidation can be performed without degrading the gate electrode 5 and gate insulating film 3.

Specifically, when the width T_{N} of the protection film 15 is set to be thin because of a trade-off between the width T_{N} and the channel width X or when as the protection film 15 an SiO₂ film is used in place of the SiN film, the embodiment is effective.

In the above, the invention has been described with reference to the first to third embodiments according to the invention, and however the invention is not limited to these embodiments. For example, the design changes, modifications of materials, and the like which those skilled in the art may make according to the state of the art at the time of this application, and embodiments based on the same technical idea as that of the invention are also included in the technical scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, a side face parallel to a channel direction of a plurality of gate electrodes provided via a gate insulating film above a semiconductor substrate being included as a part of an inner wall of an isolation groove provided between the adjacent gate electrodes, the method comprising:
forming a protection film covering the side face of the gate electrode;
etching the semiconductor substrate using the gate electrode as a mask to form the isolation groove, the side face of the gate electrode being covered with the protection film;
forming a first insulating film by oxidizing a surface of the isolation groove to fill a bottom portion of the isolation groove; and
forming a second insulating film on the first insulating film to fill an upper portion of the isolation groove including the side face of the gate electrode.

2. The method according to claim 1, wherein
the gate electrode is provided by etching the gate insulating film formed on the semiconductor substrate, a conductive film formed on the gate insulating film, and the semiconductor substrate, and
the protection film is formed on the side face of the gate electrode, on a side face of the gate insulating film, and on a side face of a recess formed on the semiconductor substrate.

3. The method according to claim 2, wherein the protection film continuously covers the gate insulating film and a side face of the semiconductor substrate.

4. The method according to claim 1, wherein the protection film includes a silicon nitride film.

5. The method according to claim 4, wherein the silicon nitride film is formed using ALD.

6. The method according to claim 1, wherein the protection film is selectively left on the side face of the gate electrode.

7. The method according to claim 1, wherein in a channel width direction perpendicular to the side face of the gate electrode, a width of the semiconductor substrate formed under the gate electrode is smaller than a width of the gate electrode.

8. The method according to claim 1, wherein
the gate electrodes are provided in parallel in a direction orthogonal to the side face of the gate electrode, and
a width in a direction orthogonal to the side face of the protection film is smaller than 22% of a spacing between the adjacent gate electrodes.

9. The method according to claim 1, wherein
the semiconductor substrate is a silicon substrate, and
the first insulating film is an SiO₂ film formed by thermally oxidizing the silicon substrate.

10. The method according to claim 1, further comprising forming a control gate electrode via an interpoly insulating film above the gate electrode and the second insulating film.

11. The method according to claim 10, wherein the interpoly insulating film includes the protection film.

12. A semiconductor device, comprising:
a gate electrode provided via a gate insulating film above a semiconductor substrate;
an isolation groove including a side face parallel to a channel direction of the gate electrode as a part of an inner wall;
a first insulating film filled in a bottom portion of the isolation groove; and
a second insulating film provided on the first insulating film to fill an upper portion of the isolation groove and having a density lower than a density of the first insulating film.

13. The device according to claim 12, wherein in a channel width direction perpendicular to a side face of the gate electrode, a width of the semiconductor substrate formed under the gate electrode is smaller than a width of the gate electrode.

14. The device according to claim 12, wherein
the semiconductor substrate is a silicon substrate, and
the first insulating film is an SiO₂ film.

15. The device according to claim 12, wherein the semiconductor substrate is a silicon substrate, and a SiGe layer and a silicon layer are sequentially stacked on a surface of the silicon substrate.
